(19) United States
(12) Patent Application Publication
(10) Pub. No.: US 2008/0290487 A1
(43) Pub. Date: Nov. 27, 2008

(54) LEAD FRAME FOR SEMICONDUCTOR DEVICE

(75) Inventors: Li-Guo ZHAO, Tianjin (CN); Zhe Li, Tianjin (CN); Zhi-Jie Wang, Tianjin (CN); Guo-Ping Lu, Tianjin (CN)

Correspondence Address: FREESCALE SEMICONDUCTOR, INC.;LAW DEPARTMENT, 7700 WEST PARMER LANE MD:TX32/PL02, AUSTIN, TX, 78729, US

(73) Assignee: FREESCALE SEMICONDUCTOR, INC., Austin, TX (US)

(21) Appl. No.: 12/099,165

(22) Filed: Apr. 8, 2008

(30) Foreign Application Priority Data
May 22, 2007 (CN) 200710105030.9

(51) Int. Cl. H01L 23/495; H01L 21/56

(52) U.S. Cl. 257/677; 438/123; 257/E23.031; 257/E21.502

(57) ABSTRACT

A lead frame for a semiconductor device includes at least one row of contact terminals and a die pad for receiving an integrated circuit die. An isolation material is located between the contact terminals and the die pad. The isolation material electrically isolates adjacent lead fingers from each other and from the die pad. The isolation material also holds the lead fingers in place during a wire bonding operation and thus the bottom of the lead frame does not have to be taped during the assembly process, which saves taping and detaping steps from being performed. The isolation material also prevents resin bleed problems that sometimes occur when using tape. If a sawing step is performed, the saw need only cut through the isolation material instead of a metal, and thus saw blade life is improved.

### BACKGROUND OF THE INVENTION

The present invention relates to integrated circuits and packaged integrated circuits and, more particularly, to a lead frame for a packaged integrated circuit.

An integrated circuit (IC) die is a small device formed on a semiconductor wafer, such as a silicon wafer. Such a die is typically cut from the wafer and packaged using a lead frame. Bond pads on the die are electrically connected to the leads of the lead frame via wire bonding. The die and bond wires are encapsulated with a protective material to form a package. The leads encapsulated in the package end in an array of terminal points outside the package. Depending on the package type, these terminal points may be used as-is, such as in a Thin Small Outline Package (TSOP), or further processed, such as by attaching spherical solder balls for a Ball Grid Array (BGA). The terminal points allow the die to be electrically connected with other circuits, such as on a printed circuit board.

The lead frame is a metal frame, usually copper or nickel alloy, that supports the IC and provides external electrical connections for the packaged chip. A lead frame usually includes a flag or die pad, and lead fingers.

Referring now to FIG. 1, an enlarged cross-sectional view of a lead frame 10 and a die 12 of a conventional packaged device are shown. The lead fame 10 includes lead fingers 14 and a die pad 16. The die 12 is attached to the die pad 16 and bonding pads 18 of the die 12 are electrically connected to the lead fingers with bond wires 20. The die 12, lead fingers 14, die pad 16 and bond wires 20 are encapsulated with a mold compound (not shown) and then a sawing process is performed to separate adjacent devices formed at the same time. An additional sawing operation also may be performed to separate inners ones of the lead fingers from the die pad 16.

FIG. 1 shows a saw blade 22 cutting one of the lead fingers 14 to separate the lead finger 14 from the die pad 16. In order to facilitate cutting and prolong the life of the saw blade 22, the lead fingers 14 are sometimes etched so that a deep cut does not have to be made. It would be advantageous to provide a lead frame that does not require sawing.

### BRIEF DESCRIPTION OF THE DRAWINGS

The foregoing summary, as well as the following detailed description of preferred embodiments of the invention, will be better understood when read in conjunction with the appended drawings. For the purpose of illustrating the invention, there is shown in the drawings embodiments that are presently preferred. It should be understood, however, that the invention is not limited to the precise arrangements and instrumentalities shown. In the drawings:

FIG. 1 is an enlarged cross-sectional view of a conventional packaged semiconductor device during the assembly process;

FIG. 2 is an enlarged cross-sectional view of a packaged semiconductor device in accordance with one embodiment of the present invention;

FIG. 3 is an enlarged bottom plan view of an embodiment of a lead frame in accordance with the present invention;

FIG. 4 is an enlarged top plan view of the lead frame of FIG. 3 with a semiconductor die being electrically connected to the lead frame;

FIG. 5 is an enlarged top plan view of a conventional dual row lead frame;

FIG. 6 is an enlarged top plan view of a dual row lead frame in accordance with one embodiment of the present invention;

FIG. 7 is an enlarged top plan view of another conventional lead frame used for packaging high power devices; and

FIG. 8 is an enlarged top plan view of a lead frame for packaging high power devices in accordance with an embodiment of the present invention.

### DETAILED DESCRIPTION OF PREFERRED EMBODIMENTS

The detailed description set forth below in connection with the appended drawings is intended as a description of the presently preferred embodiments of the invention, and is not intended to represent the only forms in which the present invention may be practiced. It is to be understood that the same or equivalent functions may be accomplished by different embodiments that are intended to be encompassed within the spirit and scope of the invention. As will be understood by those of skill in the art, the present invention can be applied to various packages and package types.

Certain features in the drawings have been enlarged for ease of illustration and the drawings and the elements thereof are not necessarily in proper proportion. Further, the invention is shown embodied in a quad flat no-lead (QFN) type package. However, those of ordinary skill in the art will readily understand the details of the invention and that the invention is applicable to other package types. In the drawings, like numerals are used to indicate like elements throughout.

In order to provide a lead frame for a semiconductor device, where the assembly process requires less sawing, the present invention provides a lead frame that has at least one row of contact terminals and a die pad for receiving an integrated circuit die. An isolation material is located between the contact terminals and the die pad. The isolation material electrically isolates adjacent lead fingers from each other. The isolation material also holds the lead fingers in place during a wire bonding operation and thus the bottom of the lead frame does not have to be taped during the assembly process, thus saving the taping and detaping steps in a typical assembly operation. The isolation material also prevents resin bleed problems that sometimes occur when using tape. If a sawing step is performed, the saw need only cut through the isolation material instead of a metal, and thus saw blade life is improved.

The present invention also provides a novel semiconductor device including a die pad for receiving an integrated circuit die and at least one row of contact terminals adjacent to the die pad. An isolation material is located between the contact terminals and the die pad. An integrated circuit die is attached to a surface of the die pad. Bond wires electrically connect bonding pads on the die to respective ones of the contact terminals.

The present invention further comprises a method of packaging a semiconductor device comprising the steps of:

forming a lead frame having a die pad, at least one row of contact terminals adjacent to the die pad, and an isolation material that connects yet separates the die pad and the contact terminals;

attaching an integrated circuit die to a top surface of the die pad;

electrically connecting bonding pads of the integrated circuit die to respective ones of the contact terminals; and

encapsulating the die, electrical connections and at least a top surface of the contact terminals with a mold compound.

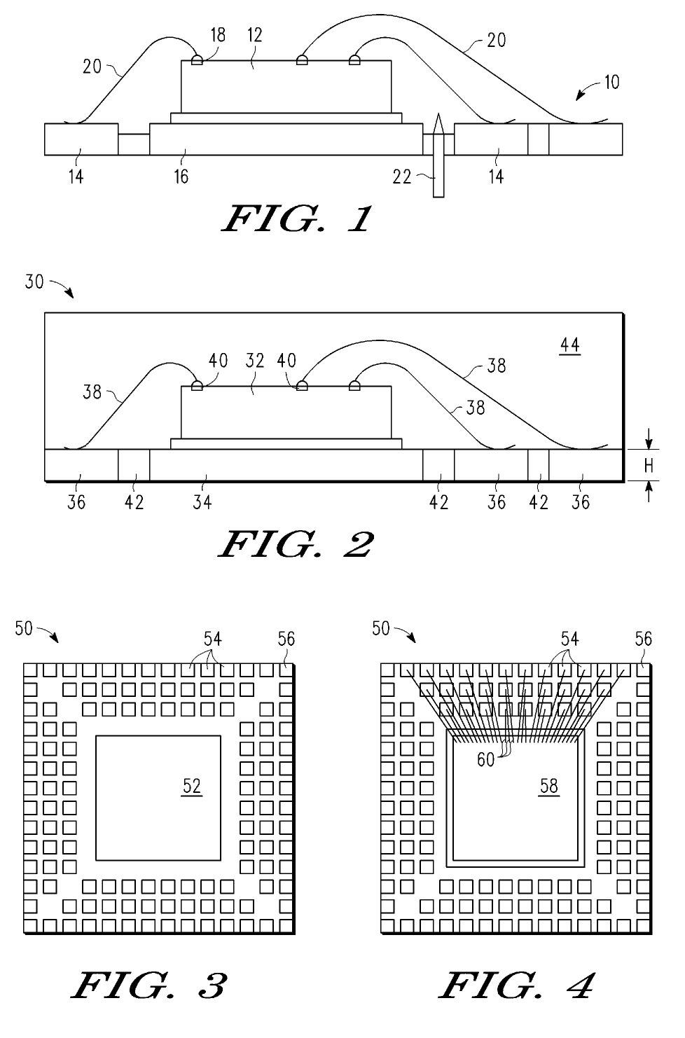

Referring now to FIG. 2, an enlarged cross-sectional view of a packaged semiconductor device 30 in accordance with an embodiment of the invention is shown. The semiconductor device 30 includes a semiconductor die 32 attached to a surface of a die pad 34. The die 32 may be of a type known to those of skill in the art, such as a circuit formed on and cut from a silicon wafer. Typical die sizes may range from 4 mm×4 mm to 12 mm×12 mm. The die 32 may have a thickness ranging from about 6 mils to about 21 mils. The die pad 34 is sized and shaped to receive the die 32. As various size die are known, it is understood that the size and shape of the die pad 34 will depend on the particular die being packaged. The die 32 is attached to the die pad 34 with an adhesive as is known by those of skill in the art.

The device 30 includes at least one row of leads or contact terminals 36 adjacent to the die pad 34. In the embodiment shown, there is a single row of the contact terminals 36 on one side of the die pad 34 and two rows of the contact terminals 36 on at least one other side of the die pad 34. As will be understood by those of skill in the art, the die pad 34 could be surrounded by multiple rows of the contact terminals. The die pad 34 and the contact terminals 36 form a lead frame. As is known, a lead frame may be formed of electrically conductive metal like copper or a metal alloy.

The die 32 is electrically connected to the contact terminals 36. More specifically, in the example shown, bond wires 38 electrically connect the contact terminals 36 to respective die bonding pads 40. The bond wires 38 are attached to the die bonding pads 40 and the contact terminals using a wire bonding process.

An isolation material 42 is provided that connects, but electrically isolates the contact terminals 36 from each other and from the die pad 34. The isolation material 42 holds the die pad 34 and the contact terminals 36 firmly so that the bottom of the lead frame (die pad 34 and contact terminals 36) does not have to be taped, as is typically done during the assembly process. That is, the isolation material 42 holds the terminals 36 in place so that a wire bonding operation can be performed.

After wire bonding is performed, an encapsulation process is performed in which the die 32, the electrical connections and wires 40 and at least a top surface of the contact terminals 36 are covered with a mold compound 44. Such encapsulation processes are well known. One benefit of the isolation material 42 is that it prevents resin bleeding, which can sometimes occur when the aforementioned tape is used during the assembly process.

The isolation material 42 adheres to the die pad 34 and the contact terminals 36. Also, the isolation material 42 is able to withstand temperatures greater than about 200° C. In one embodiment of the invention, the isolation material 42 comprises a polymer with electrical insulating properties, such as polycarbonate, polytetrafluorethylene or polycaprolactam. That is, rather than use a standard plastic mold compound, which is a mixture of materials like epoxy and silicon fillers, polycarbonate, polytetrafluorethylene or polycaprolactam are individual materials that are made by polymerization of monomers, which provides better manufacturability and lower cost. In another embodiment of the invention, the isolation material comprises ceramic material. As shown in FIG. 2, the isolation material 42 preferably has a height that is about the same as the height of the die pad 34 and the contact terminals 36.

Referring now to FIG. 3, an enlarged bottom plan view of a lead frame 50 in accordance with an embodiment of the present invention is shown. The lead frame 50 includes a die pad 52, a plurality of leads or contact terminals 54 that surround the die pad 52, and an isolation material 56 that physically connects but electrically isolates the die pad 52 and the contact terminals 54. In this embodiment, the lead frame 50 including the die pad 52 and the contact terminals 54 are formed from a copper sheet via stamping, cutting or etching. In this embodiment, there are three rows of terminals 54 that surround the die pad 52. Then the isolation material 56 is disposed between the die pad 52 and the terminals 54 via molding, such as injection molding.

FIG. 4 is an enlarged top plan view of the lead frame of FIG. 3 with a semiconductor die 58 being electrically connected to the contact terminals 54 with wires 60. As will be understood by those of skill in the art, all or most of the contact terminals 54 will be electrically connected to bonding pads on the die 58 after which a molding or encapsulation process will be performed.

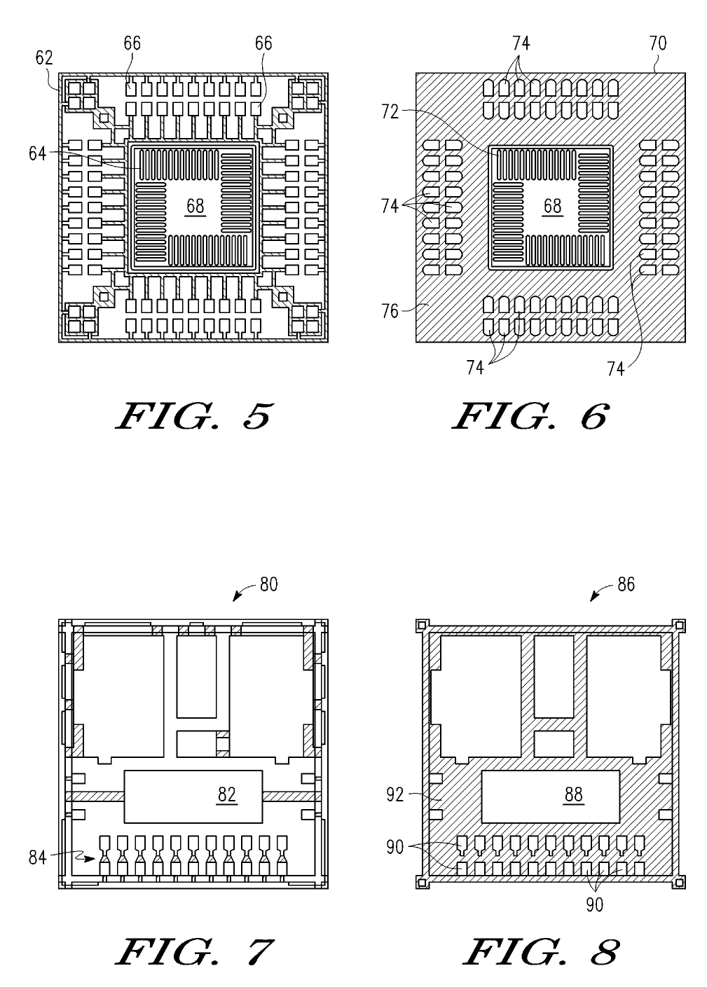

FIG. 5 is a top plan view of a typical lead frame 62 used for forming a QFN type package. The lead frame 62 has a die pad 64 and two rows of leads 66. A semiconductor die 68 is attached to a surface of the die pad 64. The two rows of leads 66 include an inner row (closer to the die pad 64) and an outer row (further from the die pad 64). The inner row of leads are attached to the die pad or a metal paddle ring that surrounds the die pad 64 with lead fingers, while the outer row are attached to a metal tie bar that extends around the perimeter of the lead frame 62. During an assembly process, the inner row leads must be separated from the paddle ring by sawing through the lead fingers, and the outer row leads must be separated from the tie bar, again with a sawing operation.

Referring now to FIG. 6, a lead frame 70 in accordance with an embodiment of the invention that is suitable for forming a QFN type package is shown. The lead frame 70 includes a die pad 72 and two rows of contact terminals 74 that surround the die pad 72. The die pad 72 is sized and shaped to receive the semiconductor die 68. Typically the die pad is formed of metal such as copper; however, other materials could be used. The contact terminals 74 also are formed of metal that provides for a good electrical connection between the die and an outside device like a printed circuit board (PCB). An isolation material 76 physically connects the die pad 72 and the contact terminals 74 and at the same time electrically isolates the die pad 72 and contact terminals 74 from each other. As previously discussed, the isolation material 76 is a material that has electrical isolation properties, can withstand temperatures of up to around 200° C., and has good adhesive properties for adhering to the die pad 72 and contact terminals 74. Preferred materials are various polymeric materials like polycarbonate, polytetrafluorethylene and polycaprolactam. Note that due to the use of the isolation material 76, tie bars, lead fingers and the paddle ring of the lead frame 62 (FIG. 5) are not necessary.

Referring now to FIG. 7, a top plan view of a conventional lead frame 80 used for packaging a high power device is shown. The lead frame 80 has at least one die pad 82 and at least one rows of leads 84. In this lead frame 80, there are two rows of leads 84 although the leads 84 are formed from the same lead fingers. Two rows of leads 84 are formed by sawing the lead fingers along two saw streets, one between the outer row of leads and the outer perimeter of the lead frame 80 and another between the leads. The lead frame 80 typically is formed from a bare metal sheet by cutting, stamping and/or etching.

FIG. 8 shows a lead frame 86 in accordance with an embodiment of the invention that is suitable for packaging a high power semiconductor device. The lead frame 86 includes a die pad 88 and two rows of contact terminals 90 adjacent to the die pad 88. The die pad 88 is sized and shaped to receive a semiconductor die (not shown). The die pad 88 and the contact terminals 90 preferably are formed of copper or another metal that is a good electrical conductor. The die pad 88 and contact terminals 90 are physically connected with an isolation material 92 that also electrically isolates the die pad 88 and contact terminals 90 from each other. In this embodiment, the isolation material 92 is a material that has electrical isolation properties, can withstand temperatures of up to around 400° C., and has good adhesive properties for adhering to the die pad 72 and contact terminals 74. Preferred materials are various polymeric materials like polycarbonate, polytetrafluorethylene and polycaprolactam.

In accordance with the lead frame of the present invention, the conventional assembly process for forming a packaged device may be modified, especially as concerns the formation of the lead frame itself. To briefly summarize one method of forming a packaged device, a lead frame is formed from a sheet of metal like copper. Preferably, a plurality of lead frames are formed substantially simultaneously from the sheet of metal, such as a 3×3 or 4×4 array of lead frames. The lead frames include a die pad and contact terminals. Next, an isolation material is disposed between the die pad and the contact terminals of the lead frames, where the isolation material comprises a polymeric material like polycarbonate, polytetrafluorethylene and polycaprolactam. Semiconductor dies are attached to the die pads and electrically connected to respective lead frame contact terminals such as by wire bonding. Finally, an encapsulation process is performed. For example, the array of lead frames may be placed in a mold and a plastic mold material is formed over the dies, wires and electrical connections. A bottom surface of the contact terminals is not covered with the mold compound, but remains exposed, and thus provide electrical connection to the dies.

Another method of forming the lead frame of the present invention is to start with a molded block of polymeric material, as described above, and then etch and drill a lead frame pattern into the molded block. Drilling may be by mechanical, chemical or laser drilling. Next, a casting or plating process is performed on the patterned block to form the metal part of the lead frame. Alternatively, the metal part of the lead frame may be formed by vapor deposition (PVD/CVD). Thus, a lead frame that has metal only where necessary is formed. As will be appreciated, with the cost of precious metals rising, saving on metal waste is advantageous.

With the use of the lead frame of the present invention, the lead frame does not have to be taped prior to wire bonding, nor de-taped later. Saw singulation does not have to be performed to separate the contact terminals from each other or from either a tie bar or paddle ring.

The description of the preferred embodiments of the present invention have been presented for purposes of illustration and description, but are not intended to be exhaustive or to limit the invention to the forms disclosed. It will be appreciated by those skilled in the art that changes could be made to the embodiments described above without departing from the broad inventive concept thereof. For example, a lead frame without a die pad could be formed, as could a lead frame with two or more die pads. In addition, the die and die pad sizes may vary to accommodate the required package design. Also, one or more die could be stacked one atop the other to form a stacked die package. It is understood, therefore, that this invention is not limited to the particular embodiments disclosed, but covers modifications within the spirit and scope of the present invention as defined by the appended claims.

1. A lead frame for a semiconductor device, the lead frame comprising:
at least one row of contact terminals;
a die pad for receiving an integrated circuit die; and
a polymer isolation material connecting the contact terminals and the die pad.

2. The lead frame of claim 1, wherein the isolation material is able to adhere to the contact terminals and the die pad, and withstand temperatures greater than about 200° C.

3. The lead frame of claim 3, wherein the isolation material is one of polycarbonate, polytetrafluorethylene and polycaprolactam.

4. The lead frame of claim 1, wherein the contact terminals, the die pad and the isolation material have substantially the same height.

5. The lead frame of claim 1, wherein the at least one row of contact terminals surrounds the die pad.

6. The lead frame of claim 5, further comprising a second row of terminals surrounding the first row of terminals, wherein the isolation material electrically isolates the terminals of the first and second rows of terminals from each other.

7. The lead frame of claim 1, wherein the contact terminals and the die pad are formed of copper.

8. The lead frame of claim 1, wherein the isolation material comprises ceramic.

9. A semiconductor device, comprising:
a die pad for receiving an integrated circuit die;
at least one row of contact terminals;
a polymer isolation material connecting the contact terminals and the die pad; and
an integrated circuit die attached to a surface of the die pad, wherein bonding pads on the die are electrically connected to respective ones of the contact terminals with bond wires.

10. The semiconductor device of claim 9, wherein the at least one row of contact terminals surrounds the die pad.

11. The semiconductor device of claim 10, further comprising a second row of contact terminals surrounding the first row of contact terminals, wherein the isolation material connects the first and second rows of terminals and electrically isolates the contact terminals from each other.

12. The semiconductor device of claim 11, further comprising an encapsulant coveting a top surface of the integrated circuit die, the first and second rows of terminals, and the isolation material, wherein at least a bottom surface of the first and second rows of contact terminals is exposed.

13. The present invention further comprises a method of packaging a semiconductor device comprising the steps of:
forming a lead frame having a die pad, at least one row of contact terminals adjacent to the die pad, and a polymer isolation material that connects yet separates the die pad and the contact terminals;
attaching an integrated circuit die to a top surface of the die pad;
electrically connecting bonding pads of the integrated circuit die to respective ones of the contact terminals; and
encapsulating the die, electrical connections ad at least a top surface of the contact terminals with a mold compound.

14. The method of packaging a semiconductor device of claim 13, wherein the electrical connecting step includes performing a wirebonding process.
